(19) United States
(12) Patent Application Publication
(10) Pub. No.: US 2025/0167094 A1
(43) Pub. Date: May 22, 2025

(54) DISPLAY DEVICE AND ELECTRONIC DEVICE

(71) Applicant: SAMSUNG DISPLAY CO., LTD., YONGIN-SI (KR)

(72) Inventors: SEDAE KI, Yongin-si (KR); DAE-YUN KOO, Yongin-si (KR); YOUNGKWAN KIM, Yongin-si (KR)

(21) Appl. No.: 18/795,510

(22) Filed: Aug. 6, 2024

(30) Foreign Application Priority Data
Nov. 20, 2023 (KR) 10-2023-0160620

(51) Int. Cl. H01L 23/498; H10K 59/131; H10K 59/90

(52) U.S. Cl. CPC H01L 23/49838; H10K 59/131; H10K 59/90

(57) ABSTRACT

A display device including: a display panel configured to display an image; and a circuit board electrically connected to the display panel, wherein the circuit board includes a plurality of power wires, a plurality of signal wires, a first connector including a plurality of first connection portions, each electrically connected to one of the power wires, a plurality of connection pads, each electrically connected to one of the first connection portions, and a second connector including a plurality of second connection portions, each electrically connected to one of the plurality of signal wires, and a first interval between the first connection portions along a first direction is different from a second interval between the connection pads along the first direction.

### CROSS-REFERENCE TO RELATED APPLICATION

This U.S. non-provisional patent application claims priority under 35 U.S.C. § 119 to Korean Patent Application No. 10-2023-0160620, filed on Nov. 20, 2023, the disclosure of which is incorporated by reference herein in its entirety.

### TECHNICAL FIELD

The present disclosure relates to a display device and an electronic device, and particularly, to a display device and an electronic device with enhanced reliability.

### DISCUSSION OF RELATED ART

A display device, which provides an image to a user, includes devices such as televisions, monitors, smartphones, and tablet computers. These devices utilize various display panels including liquid crystal display panels, organic light-emitting display panels, electrowetting display panels, and electrophoretic display panels.

An electronic device may include a flexible circuit board connected to the display panel, as well as a circuit board and a main circuit board connected to the display panel through the flexible circuit board.

### SUMMARY

The present disclosure provides a display device and an electronic device in which a connector of a circuit board and a connector of a main circuit board are easily coupled, thereby simplifying the manufacturing processes.

An embodiment of the inventive concept provides a display device including: a display panel configured to display an image; and a circuit board electrically connected to the display panel, wherein the circuit board includes a plurality of power wires, a plurality of signal wires, a first connector including a plurality of first connection portions, each electrically connected to one of the power wires, a plurality of connection pads, each electrically connected to one of the first connection portions, and a second connector including a plurality of second connection portions, each electrically connected to one of the plurality of signal wires, and a first interval between the first connection portions along a first direction is different from a second interval between the connection pads along the first direction.

The connection pads include: a plurality of first sub-pads arranged in the first direction; and a plurality of second sub-pads spaced apart from the plurality of first sub-pads in a second direction that intersects the first direction, and arranged along the first direction.

The first sub-pads and the second sub-pads are arranged in a zigzag pattern along the first direction.

An interval of the first sub-pads and an interval of the second sub-pads are same as each other.

The second interval is greater than the first interval.

Each of the first connection portions includes a plurality of first pads, and a plurality of first connection pins electrically connected to the first pads, and each of the second connection portions includes a plurality of second pads, and a plurality of second connection pins electrically connected to the second pads.

The first pads and the second pads are each arranged along the first direction, wherein the first pads are separated from each other by a first distance, and the second pads are separated from each other by the first distance.

The first pads and the second pads are each arranged along the first direction, wherein the first pads are separated from each other by a first distance and the second pads are separated from each other by a second distance different from the first distance.

A first width of each of the first connection pins along the first direction and a second width of each of the second connection pins along the first direction are different.

The first connector and the connection pads are spaced apart from each other on a plane.

The circuit board further includes connection wires for electrically connecting the first connector and the connection pads.

A number of the first connection portions is greater than a number of the second connection portions.

An embodiment of the inventive concept provides an electronic device including: a display panel configured to display an image; a circuit board electrically connected to the display panel; and a main circuit board including a power connector for supplying a power signal to the circuit board, and a signal connector for supplying an image signal, wherein the circuit board includes a plurality of power wires, a plurality of signal wires, a first connector including a plurality of first connection portions, each electrically connected to one of the power wires, a plurality of connection pads connected to the power connector, each electrically connected to one of the first connection portions, and a second connector connected to the signal connector, and including a plurality of second connection portions each electrically connected to one of the plurality of signal wires, and a first interval of the first connection portions along a first direction and a second interval of the connection pads along the first direction are different.

The first connector and the connection pads are spaced apart from each other on a plane, and the circuit board further includes connection wires electrically connecting the first connector and the connection pads.

The power connector includes: a first jig plate; and a plurality of first jig pins disposed on the first jig plate, and in contact with the connection pads.

An interval of the first jig pins along the first direction is the same as the second interval.

The signal connector includes: a second jig plate; and a plurality of second jig pins disposed on the second jig plate, and in contact with the second connection portions.

An interval of the second jig pins along the first direction is the same as a third interval of the second connection portions along the first direction.

A number of the first connection portions is greater than a number of the second connection portions.

A first width of each of the first connection portions along the first direction is different from a second width of each of the second connection portions along the first direction.

### BRIEF DESCRIPTION OF THE DRAWINGS

The accompanying drawings are included to enhance understanding of the inventive concept. They are incorporated into and constitute a part of this specification. The drawings illustrate embodiments of the inventive concept and, together with the description, help explain its principles. In the drawings:

FIG. 1 is a perspective view of an electronic device according to an embodiment of the inventive concept;

FIG. 2 is a cross-sectional view of a display device included in the electronic device in FIG. 1;

FIG. 3 is a cross-sectional view of a display panel illustrated in FIG. 2;

FIGS. 4A, 4B and 4C are diagrams illustrating an electronic device according to an embodiment of the inventive concept;

FIG. 5 is a diagram illustrating a cross-section of a display device corresponding to a pixel illustrated in FIG. 4A;

FIG. 6 is an enlarged view of a pad portion according to the embodiment of the inventive concept illustrated in FIG. 4A;

FIGS. 7A and 7B are diagrams illustrating the coupling of a pad portion and a power connector according to an embodiment of the inventive concept;

FIG. 8A is an enlarged view of a first connector according to an embodiment of the inventive concept illustrated in FIG. 4A;

FIG. 8B is a perspective view of a first connector according to an embodiment of the inventive concept;

FIG. 9 is an enlarged view of a second connector illustrated in FIG. 4A; and

FIGS. 10A and 10B are diagrams illustrating the coupling of a second connector and a signal connector according to an embodiment of the inventive concept.

### DETAILED DESCRIPTION OF THE EMBODIMENTS

In the inventive concept, various modifications and forms may be applied, and specific embodiments are illustrated in the drawings and described in detail in the text. However, this is not intended to limit the inventive concept to these specific forms; it should be understood to include all changes, equivalents, and substitutes within the spirit and scope of the inventive concept.

In this specification, when a component (or region, layer, portion, etc.) is referred to as “on”, “connected”, or “coupled” to another component, it means that it is directly on, connected to, or coupled with the other component, or a third component can be disposed between them.

The same reference numerals or symbols refer to the same elements. In addition, in the drawings, thicknesses, ratios, and dimensions of components are exaggerated for effective description of the technical content.

“And/or” includes all combinations of one or more of the associated elements.

Terms such as first and second may be used to describe various components, but the components should not be limited by these terms. These terms are used for the purpose of distinguishing one component from another. For example, a first component may be referred to as a second component, and similarly, a second component may be referred to as a first component. Singular expressions include plural expressions unless the context clearly indicates otherwise.

In addition, terms such as “below”, “lower”, “above”, and “upper” are used to describe the relationship between components shown in the drawings. These terms are relative concepts and are described based on the directions indicated in the drawings.

Unless otherwise defined, all terms (including technical and scientific terms) used in this specification have the same meaning as commonly understood by one of ordinary skill in the art to which this invention belongs. In addition, terms defined in commonly used dictionaries should be interpreted as having meanings consistent with those in the context of the related technology, and should not be interpreted as overly idealized or too formal unless explicitly defined here.

Terms such as “include” or “have” are intended to indicate the presence of a feature, number, step, action, component, part, or combination thereof described in the specification, and it should be understood that they do not preclude the possibility of the presence or addition of one or more other features, numbers, steps, operations, components, parts, or combinations thereof.

Hereinafter, embodiments of the inventive concept will be described with reference to the drawings.

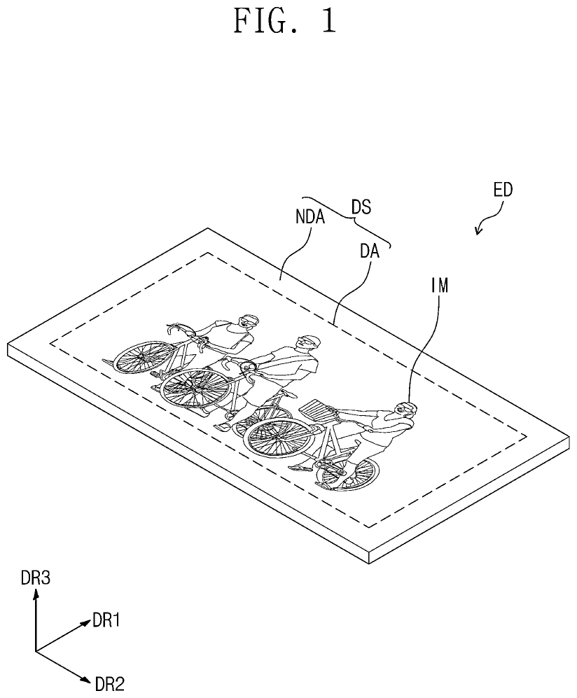

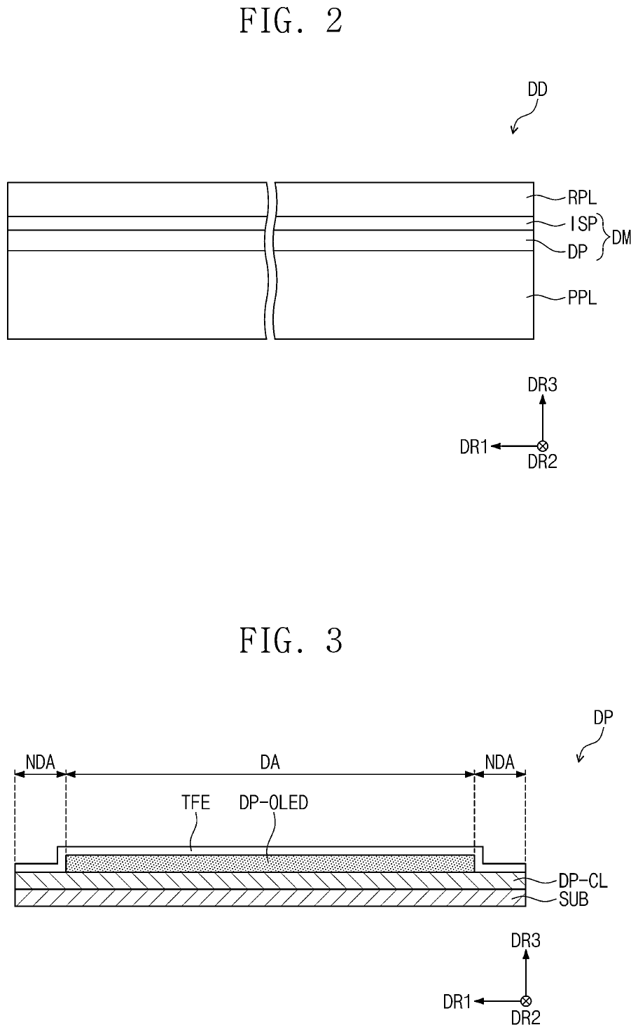

FIG. 1 is a perspective view of an electronic device according to an embodiment of the inventive concept. FIG. 2 is a cross-sectional view of a display device included in the electronic device in FIG. 1. FIG. 3 is a cross-sectional view of a display panel illustrated in FIG. 2.

Referring to FIG. 1, an electronic device ED according to an embodiment of the inventive concept may have a rectangular shape having short sides extending in a first direction DR1, and long sides extending in a second direction DR2 crossing the first direction DR1. However, an embodiment of the inventive concept is not limited thereto, and the electronic device ED may have various shapes such as a circle, and a polygon.

Hereinafter, a direction substantially perpendicular to the plane defined by the first direction DR1 and the second direction DR2 is defined as a third direction DR3. Additionally, in the present specification, “when seen on a plane” refers to a view in the third direction DR3.

The upper surface of the electronic device ED may be a display surface DS, and the display surface DS may have a plane defined by the first direction DR1 and the second direction DR2. Images IM generated by the electronic device ED may be supplied to a user through the display surface DS.

The display surface DS may include a display region DA and a non-display region NDA around the display region DA. The display region DA may display an image, and the non-display region NDA may not display the image. The non-display region NDA may surround the display region DA, and may define a border of the electronic device ED, which is printed in a crystal color.

The electronic device ED may include a display device DD (see FIG. 2). The display device DD will be described below in detail.

Referring to FIG. 2, the display device DD may include a display module DM, an anti-reflective layer RPL disposed on the display module DM, and a panel protection layer PPL disposed under the display module DM. The display module DM may include a display panel DP and an input-sensing portion ISP disposed on the display panel DP. The display panel DP may be a flexible panel. For example, the display panel DP may include a flexible substrate and a plurality of elements disposed on the flexible substrate.

The display panel DP according to an embodiment of the inventive concept may be a light-emitting display panel, but is not specially limited thereto. For example, the display panel DP may be an organic light-emitting display panel or an inorganic light-emitting display panel. A light-emitting layer of the organic light-emitting display panel may include an organic light-emitting material. A light-emitting layer of the inorganic light-emitting display panel may include quantum dots, quantum rods, etc. Hereinafter, the display panel DP will be described as the organic light-emitting display panel.

The input-sensing portion ISP may include a plurality of sensors for sensing external inputs in a capacitive manner. During the manufacture of the display device DD, the input-sensing portion ISP may be directly formed on the display panel DP without the need for a separate adhesive layer.

The anti-reflective layer RPL may be disposed on the input-sensing portion ISP. When the display device DD is manufactured, the anti-reflective layer RPL may be directly formed on the input-sensing portion ISP. The anti-reflective layer RPL may be an external light reflection preventing film. The anti-reflective layer RPL may reduce the reflectance of external light entering the display panel DP from above the electronic device ED.

The input-sensing portion ISP may be directly formed on the display panel DP, and the anti-reflective layer RPL may be directly formed on the input-sensing portion ISP, but an embodiment of the inventive concept is not limited thereto. For example, the input-sensing portion ISP may be separately manufactured and attached to the display panel DP by an adhesive layer, and the anti-reflective layer RPL may be separately manufactured and attached to the input-sensing portion ISP by an adhesive layer.

The panel protection layer PPL may be disposed under the display panel DP. The panel protection layer PPL may protect a lower portion of the display panel DP. The panel protection layer PPL may include a flexible plastic material. For example, the panel protection layer PPL may include polyethylene terephthalate (PET).

Referring to FIG. 3, the display panel DP may include a substrate SUB, a circuit element layer DP-CL disposed on the substrate SUB, a display element layer DP-OLED disposed on the circuit element layer DP-CL, and a thin-film encapsulation layer TFE disposed on the display element layer DP-OLED.

The substrate SUB may include a display region DA and a non-display region NDA around the display region DA. The substrate SUB may include glass or a flexible plastic material such as polyimide (PI). The display element layer DP-OLED may be disposed on the display region DA.

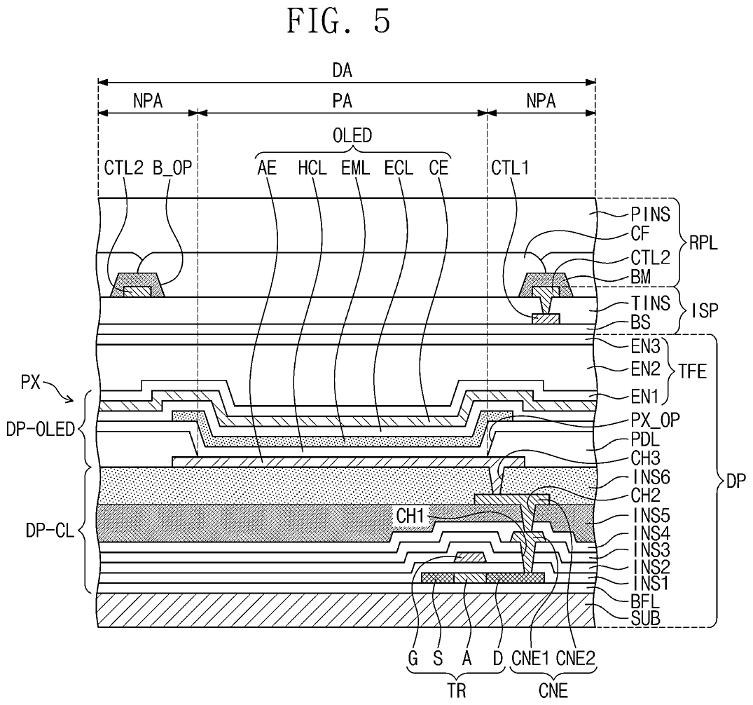

A plurality of pixels may be disposed on the circuit element layer DP-CL and the display element layer DP-OLED. Each of the pixels may include a transistor disposed on the circuit element layer DP-CL, and a light-emitting element disposed on the display element layer DP-OLED to be connected to a transistor. The configuration of the pixel will be described in detail in FIG. 5.

The thin-film encapsulation layer TFE may be disposed on the circuit element layer DP-CL to cover the display element layer DP-OLED. The thin-film encapsulation layer TFE protects the pixels from moisture, oxygen, and external foreign matter.

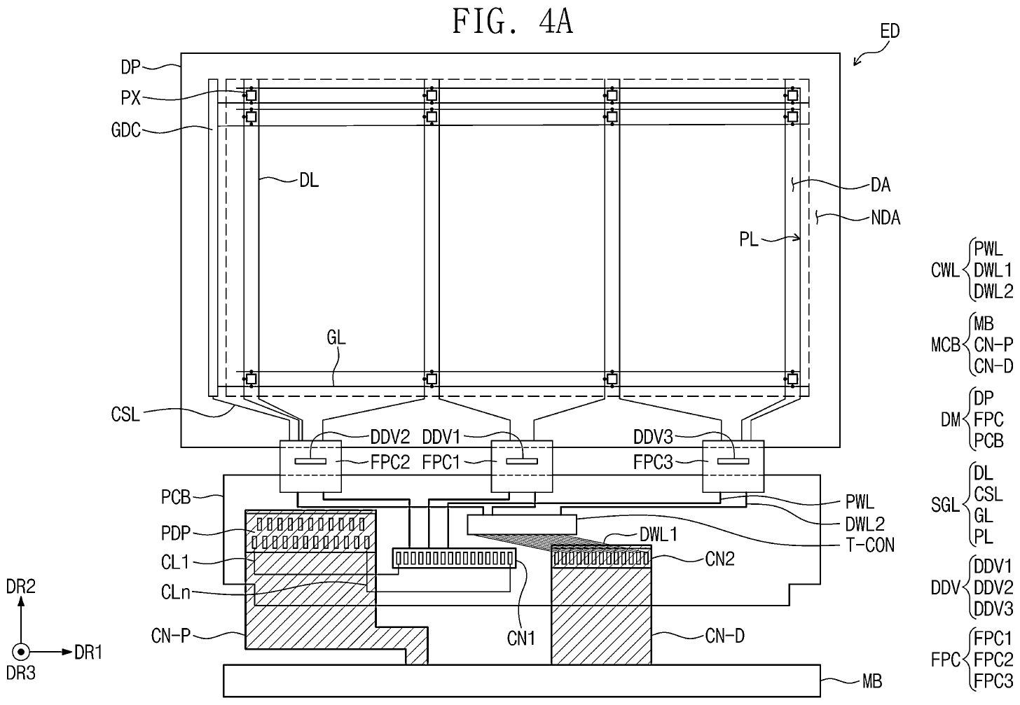

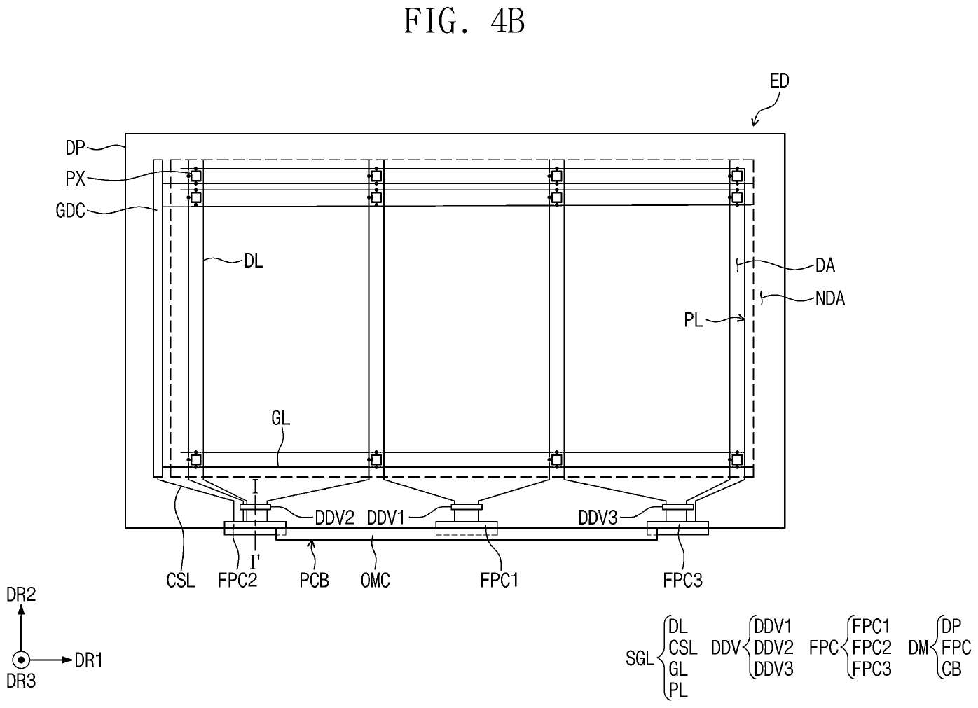

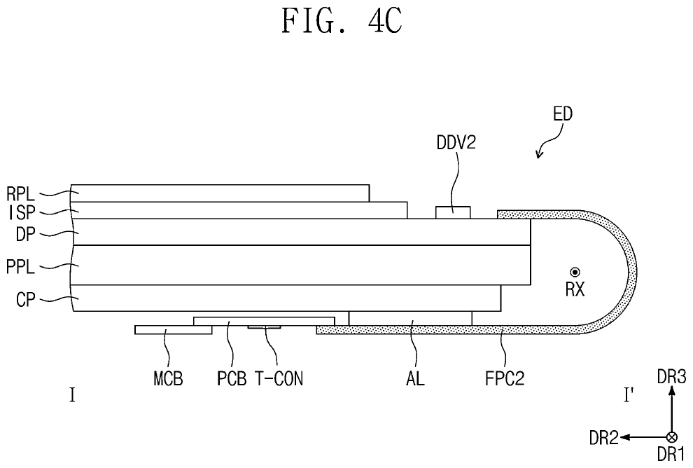

FIGS. 4A to 4C are diagrams illustrating an electronic device according to an embodiment of the inventive concept. Specifically, FIG. 4A illustrates a state before bending a flexible circuit board FPC, a circuit board PCB (or printed circuit board), and a main circuit board MCB which are connected to a display panel DP. FIG. 4B illustrates a state in which the flexible circuit board FPC, the circuit board PCB, and the main circuit board MCB which are connected to the display panel DP are bent. FIG. 4C is a cross-sectional view of an electronic device ED according to an embodiment of the inventive concept taken along line I-I′ in FIG. 4B.

Referring to FIG. 4A, the electronic device ED may include a display module DM and the main circuit board MCB. The display module DM may include the display panel DP, the flexible circuit board FPC connected to the display panel DP, the circuit board PCB connected to the flexible circuit board FPC, a scan driver GDC, a plurality of signal lines SGL, a plurality of data drivers DDV, and a plurality of pixels PX.

The display panel DP may include a display region DA and a non-display region NDA around the display region DA. The non-display region NDA may surround the display region DA. The display region DA may be a region in which an image is displayed, and the non-display region NDA may be a region in which the image is not displayed.

The data drivers DDV may be disposed in the non-display region NDA of the display panel DP. The data drivers DDV may be disposed adjacent to the border of the display panel DP. The data drivers DDV may be arranged in the second direction DR2.

The data drivers DDV may include a first data driver DDV1, a second data driver DDV2, and a third data driver DDV3. When viewed on a plane, the first data driver DDV1 may overlap the central portion of the display panel DP.

The second data driver DDV2 may be spaced apart from the first data driver DDV1 in the second direction DR2. When viewed in the first direction DR1, the second data driver DDV2 may be disposed on the left side of the first data driver DDV1.

The third data driver DDV3 may be spaced apart from the first data driver DDV1 in the second direction DR2. When viewed in the first direction DR1, the third data driver DDV3 may be disposed on the right side of the first data driver DDV1.

The first to third data drivers DDV1 to DDV3 may be mounted on the flexible circuit board FPC. Each of the first to third data drivers DDV1 to DDV3 mounted on the flexible circuit board FPC may be electrically connected to the display panel DP to supply an electrical signal for driving the display panel DP.

The flexible circuit board FPC may be connected to the display panel DP. One end of the flexible circuit board FPC may be disposed in the non-display region NDA of the display panel DP. The flexible circuit board FPC may be disposed adjacent to the border of the display panel DP.

The flexible circuit board FPC may be disposed on pads disposed on the display panel DP. The flexible circuit board FPC may be electrically connected to the pads through an anisotropic conductive adhesive layer. Accordingly, the flexible circuit board FPC may be electrically connected to the display panel DP through the pads.

The flexible circuit board FPC may include a first flexible circuit board FPC1, a second flexible circuit board FPC2, and a third flexible circuit board FPC3. When viewed on a plane, the first flexible circuit board FPC1 may overlap the central portion of the display panel DP.

The second flexible circuit board FPC2 may be spaced apart from the first flexible circuit board FPC1 in the second direction DR2. When viewed in the first direction DR1, the second flexible circuit board FPC2 may be disposed on the left side of the first flexible circuit board FPC1.

The third flexible circuit board FPC3 may be spaced apart from the first flexible circuit board FPC1 in the second direction DR2. When viewed in the first direction DR1, the third flexible circuit board FPC3 may be disposed on the right side of the first flexible circuit board FPC1.

The first data driver DDV1 may be mounted on the first flexible circuit board FPC1. The first data driver DDV1 may be electrically connected to some of the signal lines SGL through the first flexible circuit board FPC1. The second data driver DDV2 may be mounted on the second flexible circuit board FPC2. The second data driver DDV2 may be electrically connected to some of the signal lines SGL through the second flexible circuit board FPC2. The third data driver DDV3 may be mounted on the third flexible circuit board FPC3. The third data driver DDV3 may be electrically connected to some of the signal lines SGL through the third flexible circuit board FPC3.

FIG. 4A illustrates three flexible circuit boards FPC and three data drivers DDV, but the numbers of the flexible circuit boards FPC and the data drivers DDV are not limited to these quantities.

The circuit board PCB may be connected to the flexible circuit board FPC. A first side of the flexible circuit board FPC may be connected to the display panel DP. A second side of the flexible circuit board FPC, opposite to the first side in the first direction DR1 may be connected to the circuit board PCB. The circuit board PCB may be electrically connected to the display panel DP through the flexible circuit board FPC.

When viewed on a plane, the circuit board PCB may have a T-shape. However, the shape of the circuit board PCB is not limited thereto, and a width of the circuit board PCB in the second direction DR2 may change along the first direction DR1.

The circuit board PCB may include a timing controller T-CON, a pad portion PDP, a first connector CN1, and a second connector CN2. The timing controller T-CON may be spaced apart from the first flexible circuit board FPC1 in the first direction DR1. The pad portion PDP, the first connector CN1, and the second connector CN2 may be spaced apart from each other. The pad portion PDP and the second connector CN2 may be connected to the main circuit board MCB. Detailed descriptions thereof will be provided later.

The circuit board PCB may further include connection wires CL1 to CLn and circuit wires CWL. The connection wires CL1 to CLn may electrically connect the pad portion PDP and the first connector CN1 which are spaced apart from each other. The pad portion PDP may transmit a signal to the first connector CN1 through the connection wires CL1 to CLn.

The circuit wires CWL may include power wires PWL, and signal wires DWL1 and DWL2. The power wires PWL may electrically connect the first connector CN1 and the flexible circuit board FPC. The power wires PWL may be connected to each of the first flexible circuit board FPC1, the second flexible circuit board FPC2, and the third flexible circuit board FPC3. The power wires PWL may transmit a power signal received form the main circuit board MCB to each of the first flexible circuit board FPC1, the second flexible circuit board FPC2, and the third flexible circuit board FPC3.

The signal wires DWL1 and DWL2 may include first signal wires DWL1 and second signal wires DWL2. The first signal wires DWL1 may electrically connect the second connector CN2 and the timing controller T-CON. The second signal wires DWL2 may electrically connect the timing controller T-CON and the flexible circuit board FPC. The first signal wires DWL1 may transmit an image signal received from the main circuit board MCB to the timing controller T-CON. The timing controller T-CON may generate a data signal by converting the data format of the image signal according to an interface specification. The second signal wires DWL2 may transmit the data signal received from the timing controller T-CON to each of the first flexible circuit board FPC1, the second flexible circuit board FPC2, and the third flexible circuit board FPC3.

The main circuit board MCB may be electrically connected to the circuit board PCB. The main circuit board MCB may transmit an electrical signal to the circuit board PCB. A voltage generation unit may be disposed on the main circuit board MCB. The voltage generation unit may generate voltages necessary for the operation of the display panel DP.

The main circuit board MCB may include a main board MB, a power connector CN-P, and a signal connector CN-D. The main board MB may include the voltage generation unit for generating voltages necessary for the operation of the display panel DP. The main board MB may transmit a power signal to the circuit board PCB through the power connector CN-P. In addition, the main board MB may transmit a data signal to the circuit board PCB through the signal connector CN-D.

The power connector CN-P may be disposed on the pad portion PDP. The power connector CN-P may be electrically connected to the pad portion PDP. After the power connector CN-P is connected to the pad portion PDP, the main board MB may transmit the power signal to the power wires PWL of the circuit board PCB through the power connector CN-P and the pad portion PDP which are connected to each other.

The signal connector CN-D may be disposed on the second connector CN2. The signal connector CN-D may be electrically connected to the second connector CN2. After the signal connector CN-D is connected to the second connector CN2, the main board MB may transmit the data signal to the signal wires DWL1 and DWL2 of the circuit board PCB through the signal connector CN-D and the second connector CN2 which are connected to each other. A detailed configuration of the power connector CN-P, the pad portion PDP, the signal connector CN-D, and the second connector CN2 will be provided in detail later.

A plurality of elements may be further disposed on the main board MB. The elements may include a resistor, a capacitor, an inductor, and a plurality of terminals.

The scan driver GDC may generate a plurality of scan signals, and may output the scan signals to a plurality of scanning lines GL to be described later. The scan driver GDC may output another control signal to a driving circuit of the pixels PX.

The scan driver GDC may include a plurality of transistors formed through the same process as that for the data driver DDV of the pixels PX, for example, a low temperature polycrystalline silicon (LTPS) process, or a low temperature polycrystalline oxide (LTPO) process.

The signal lines SGL may include scanning lines GL, data lines DL, a power line PL, and a control signal line CSL. The scanning lines GL may extend in the second direction DR2 to be connected to the scan driver GDC. The scanning lines GL may be respectively connected to corresponding pixels PX among the pixels PX, and the data lines DL may be respectively connected to corresponding pixels PX among the pixels PX. The power line PL may be connected to the pixels PX. The control signal line CSL may be connected to the scan driver GDC to supply control signals.

The data lines DL may be connected to the data drivers DDV and the flexible circuit board FPC. The data lines DL may be electrically connected to the flexible circuit board FPC through data pads.

The power line PL may be electrically connected to each of the first flexible circuit board FPC1, the second flexible circuit board FPC2, and the third flexible circuit board FPC3. The power line PL may supply a driving voltage from the circuit board PCB to the pixels PX.

The control signal line CSL may be connected to the scan driver GDC. The control signal line CSL may be electrically connected to each of the first flexible circuit board FPC1, the second flexible circuit board FPC2, and the third flexible circuit board FPC3 through control signal pads.

The timing controller T-CON may control the operation of the scan driver GDC and the data drivers DDV. The timing controller T-CON may generate a scan control signal and a data control signal in response to control signals received from the main board MB.

The scan control signal may be supplied to the scan driver GDC through the control signal line CSL. The data control signal may be supplied to the data drivers DDV. The timing controller T-CON may receive image signals from the main board MB, generate data signals by converting the data format of the image signals according to an interface specification, and supply the data signals to the data drivers DDV.

The scan driver GDC may generate a plurality of scan signals in response to the scan control signal. The scan signals may be applied to the pixels PX through the scanning lines GL. The scan signals may be sequentially applied to the pixels PX.

The data drivers DDV may generate a plurality of data voltages corresponding to the data signals in response to the data control signal. The data voltages may be applied to the pixels PX through the data lines DL.

The pixels PX may be supplied with the data voltages in response to the scan signals. The pixels PX may display an image by emitting light with a luminance corresponding to the data voltages.

Referring to FIGS. 4B and 4C, the display device DD may further include a cover panel CP. The cover panel CP may be disposed under a panel protection layer PPL. The cover panel CP may be bonded to the panel protection layer PPL through an adhesive layer. The cover panel CP may support the rear surface of the display panel DP. The rear surface of the display panel DP may be defined as a surface opposite, in the third direction DR3, to the upper surface where the input-sensing portion ISP is located.

The borders of the input-sensing portion ISP, the anti-reflective layer RPL, and the cover panel CP may be positioned more inward than the borders of the display panel DP and the panel protection layer PPL. The display panel DP and the panel protection layer PPL may have the same width.

According to an embodiment of the inventive concept, each of the flexible circuit boards FPC may be bent with respect to an imaginary axis parallel to the second direction DR2 such that the circuit board PCB and the main circuit board MCB are disposed under the display panel DP.

As illustrated in FIG. 4C, the second flexible circuit board FPC2 may be bent with respect to the bending axis RX. However, this is an example, and the number of the bending axes RX may be two or more.

The first and third flexible circuit boards FPC1 and FPC3 may be bent while having the substantially same shape.

When the flexible circuit board FPC is bent, a portion of the flexible circuit board FPC may be disposed on the lower surface of the cover panel CP. As illustrated in FIG. 4C, an adhesive layer AL may be disposed between the first flexible circuit board FPC1 and the cover panel CP. The first flexible circuit board FPC1 and the cover panel CP may be bonded to each other through the adhesive layer AL. The second and third flexible circuit boards FPC2 and FPC3 and the cover panel CP may be bonded to each other through the adhesive layer AL.

When the flexible circuit board FPC is bent, the main circuit board MCB may be disposed under the display panel DP. Hereinafter, when viewed on a plane, a portion of the main circuit board MCB exposed from the display panel DP to the outside may be defined as an exposed substrate OMC.

FIG. 5 is a diagram illustrating a cross-section of a display device corresponding to any one pixel illustrated in FIG. 4A.

Referring to FIG. 5, a pixel PX may include a transistor TR and a light-emitting element OLED. The light-emitting element OLED may include a first electrode AE (or anode), a second electrode CE (or cathode), a hole control layer HCL, an electron control layer ECL, and a light-emitting layer EML. The transistor TR and the light-emitting element OLED may be disposed on a substrate SUB. One transistor TR is illustrated, but the pixel PX may actually include a plurality of transistors and at least one capacitor for driving the light-emitting element OLED.

A display region DA may include a light-emitting region PA corresponding to each of the pixels PX and a non-light-emitting region NPA around the light-emitting region PA. The light-emitting element OLED may be disposed in the light-emitting region PA.

A buffer layer BFL may be disposed on the substrate SUB, and may be an inorganic layer. A semiconductor pattern may be disposed on the buffer layer BFL. The semiconductor pattern may include polysilicon, amorphous silicon, or a metal oxide.

The semiconductor pattern may be doped with an N-type dopant or a P-type dopant. The semiconductor pattern may include a heavily doped region and a lightly doped region. The heavily doped region may have a higher conductivity than the lightly doped region, and may serve as a source electrode and a drain electrode of the transistor TR. The lightly doped region may serve as an active (or channel) region of the transistor TR.

A source S, an active A, and a drain D of the transistor TR may be formed from the semiconductor pattern. A first insulating layer INS1 may be disposed on the semiconductor pattern. A gate G of the transistor TR may be disposed on the first insulating layer INS1. A second insulating layer INS2 may be disposed on the gate G. A third insulating layer INS3 may be disposed on the second insulating layer INS2.

A connection electrode CNE may include a first connection electrode CNE1 and a second connection electrode CNE2 to connect the transistor TR and the light-emitting element OLED. The first connection electrode CNE1 may be disposed on the third insulating layer INS3, and may be connected to the drain D through a first contact hole CH1 in the first to third insulating layers INS1 to INS3.

A fourth insulating layer INS4 may be disposed on the first connection electrode CNE1. A fifth insulating layer INS5 may be disposed on the fourth insulating layer INS4. The second connection electrode CNE2 may be disposed on the fifth insulating layer INS5. The second connection electrode CNE2 may be connected to the first connection electrode CNE1 through a second contact hole CH2 in the fourth and fifth insulating layers INS4 and INS5.

A sixth insulating layer INS6 may be disposed on the second connection electrode CNE2. Layers from the buffer layer BFL to the sixth insulating layer INS6 may be part of a circuit element layer DP-CL. Each of the first to sixth insulating layers INS1 to INS6 may be an inorganic layer or an organic layer.

The first electrode AE may be disposed on the sixth insulating layer INS6. The first electrode AE may be connected to the second connection electrode CNE2 through a third contact hole CH3 in the sixth insulating layer INS6. A pixel-defining film PDL, with an opening PX_OP that exposes a predetermined portion of the first electrode AE, may be disposed on the first electrode AE and the sixth insulating layer INS6.

The hole control layer HCL may be disposed on the first electrode AE and the pixel-defining film PDL. The hole control layer HCL may include a hole transport layer and a hole injection layer.

The light-emitting layer EML may be disposed on the hole control layer HCL. The light-emitting layer EML may be disposed in a region corresponding to the opening PX_OP. The light-emitting layer EML may include an organic material and/or an inorganic material. The light-emitting layer EML may generate light having any one of red, green, or blue colors.

The electron control layer ECL may be disposed on the light-emitting layer EML and the hole control layer HCL. The electron control layer ECL may include an electron transport layer and an electron injection layer. The hole control layer HCL and the electron control layer ECL may be commonly disposed in both the light-emitting region PA and the non-light-emitting region NPA.

The second electrode CE may be disposed on the electron control layer ECL. The second electrode CE may be commonly disposed in the pixels PX. A layer on which the light-emitting element OLED is disposed may be defined as a display element layer DP-OLED.

A thin-film encapsulation layer TFE may be disposed on the second electrode CE to cover the pixel PX. The thin-film encapsulation layer TFE may include a first encapsulation layer EN1 disposed on the second electrode CE, a second encapsulation layer EN2 disposed on the first encapsulation layer EN1, and a third encapsulation layer EN3 disposed on the second encapsulation layer EN2.

The first and third encapsulation layers EN1 and EN3 may include an inorganic insulating layer, and may protect the pixel PX from moisture/oxygen. The second encapsulation layer EN2 may include an organic insulating layer, and may protect the pixel PX from foreign matters such as dust particles.

A first voltage may be applied to the first electrode AE through the transistor TR, and a second voltage having a lower level than the first voltage may be applied to the second electrode CE. A hole and an electron injected into the light-emitting layer EML may combine to form an exciton. When the exciton transitions to a ground state, the light-emitting element OLED may emit light.

An input-sensing portion ISP may be disposed on the thin-film encapsulation layer TFE. The input-sensing portion ISP may be directly manufactured on the upper surface of the thin-film encapsulation layer TFE.

A base layer BS may be disposed on the thin-film encapsulation layer TFE, and the base layer BS may include an inorganic insulating layer. At least one inorganic insulating layer may be applied on the thin-film encapsulation layer TFE as the base layer BS.

The input-sensing portion ISP may include a first conductive pattern CTL1 and a second conductive pattern CTL2 disposed on the first conductive pattern CTL1. The first conductive pattern CTL1 may be disposed on the base layer BS. An insulating layer TINS may be disposed on the base layer BS to cover the first conductive pattern CTL1. The insulating layer TINS may include an inorganic insulating layer or an organic insulating layer. The second conductive pattern CTL2 may be disposed on the insulating layer TINS.

The first and second conductive patterns CTL1 and CTL2 may overlap the non-light-emitting region NPA. The first and second conductive patterns CTL1 and CTL2 may be disposed on the non-light-emitting region NPA between the light-emitting regions PA, and may have a mesh shape.

The first and second conductive patterns CTL1 and CTL2 may form sensors of the input-sensing portion ISP described above. For example, the first and second conductive patterns CTL1 and CTL2, having a mesh shape, may be separated from each other in a predetermined region to form the sensors. The second conductive pattern CTL2 may be partially connected to the first conductive pattern CTL1.

An anti-reflective layer RPL may be disposed on the second conductive pattern CTL2. The anti-reflective layer RPL may include a black matrix BM and a plurality of color filters CF. The black matrix BM may overlap the non-light-emitting region NPA, and the color filters CF may respectively overlap the light-emitting regions PA.

The black matrix BM may be disposed on the insulating layer TINS to cover the second conductive pattern CTL2. An opening B_OP overlapping the light-emitting region PA and the opening PX_OP may be defined in the black matrix BM. The black matrix BM may absorb and block light. The opening B_OP may have a greater width than the opening PX_OP.

The color filters CF may be disposed on the insulating layer TINS and the black matrix BM. The color filters CF may be respectively disposed on the openings B_OP. A planarization insulating layer PINS may be disposed on the color filters CF. The planarization insulating layer PINS may provide a flat upper surface.

When external light propagates toward the display panel DP is reflected back to an external user, the display panel DP may act like a mirror, causing the user to see the external light. To prevent this phenomenon, the anti-reflective layer RPL may include, for example, a plurality of color filters CF that match the colors of the pixels PX in the display panel DP. These color filters CF may filter the external light to have the same colors as those of the pixels PX, making the external light invisible to the user.

However, an embodiment of the inventive concept is not limited thereto, and the anti-reflective layer RPL may include a polarization film for reducing the reflectance of external light. The polarization film may be separately manufactured to be attached to the input-sensing portion ISP by an adhesive layer. The polarization film may include a retarder and/or a polarizer.

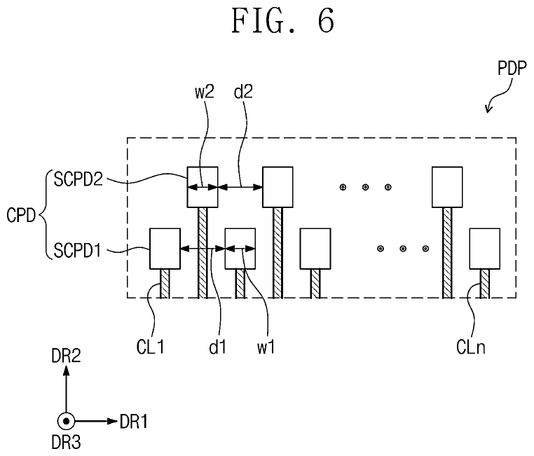

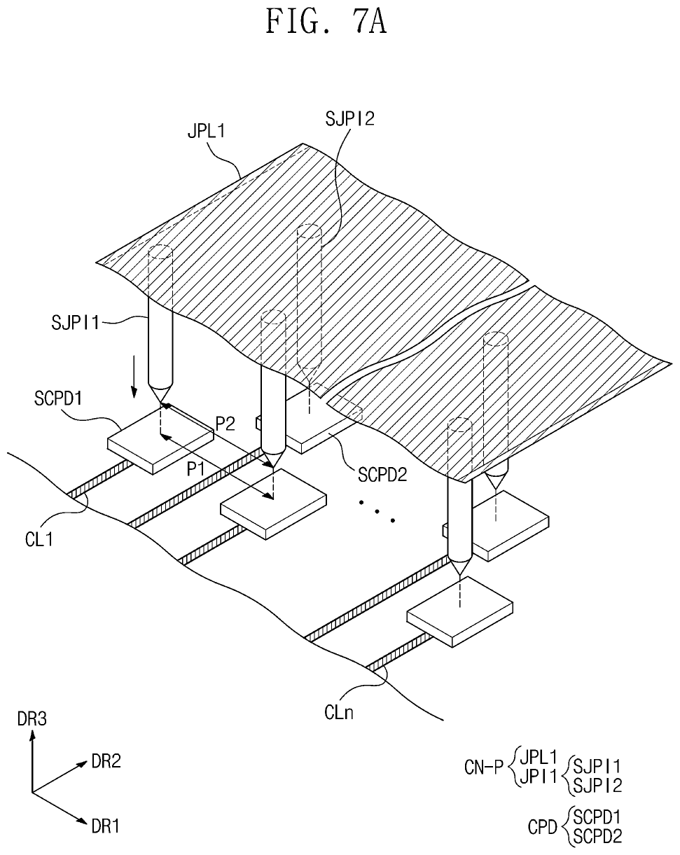

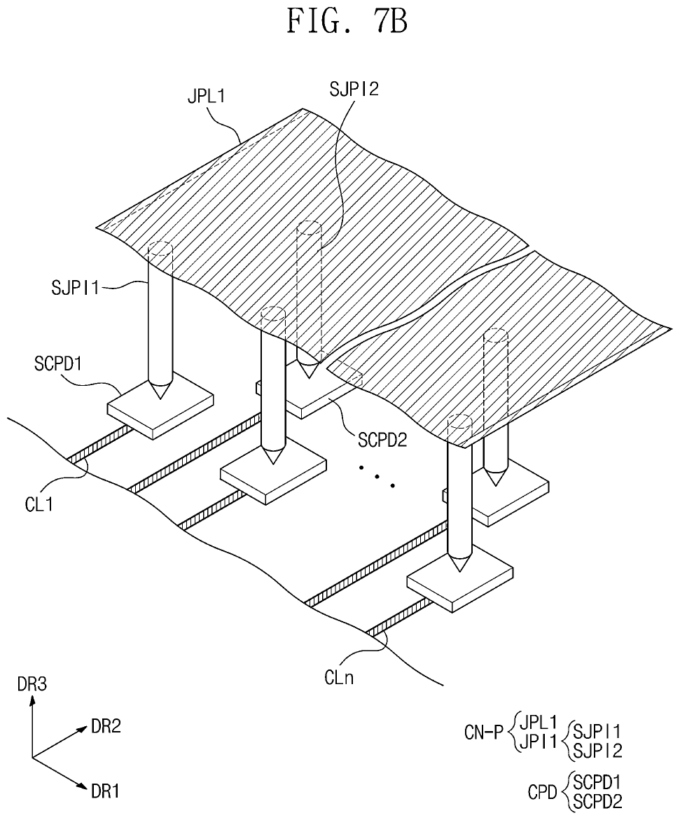

FIG. 6 is an enlarged view of a pad portion according to the embodiment of the inventive concept illustrated in FIG. 4A. FIGS. 7A and 7B are diagrams illustrating the coupling of the pad portion and a power connector according to an embodiment of the inventive concept.

Referring to FIG. 6, a pad portion PDP may include a plurality of connection pads CPD. The connection pads CPD may be arranged in the first direction DR1. The connection pads CPD may include a plurality of first sub-pads SCPD1 and a plurality of second sub-pads SCPD2. The first sub-pads SCPD1 and the second sub-pads SCPD2 may each be arranged in the first direction DR1. The first sub-pads SCPD1 and the second sub-pads SCPD2 may be spaced apart from each other with respect to the second direction DR2.

The first sub-pads SCPD1 may be spaced apart from each other by a first distance d1 in the first direction DR1. The second sub-pads SCPD2 may be spaced apart from each other by a second distance d2 in the first direction DR1. The first distance d1 and the second distance d2 may be the same. For example, the first distance d1 and the second distance d2 may be each about 0.4 mm to about 0.6 mm.

When viewed in the second direction DR2, the second sub-pads SCPD2 may be positioned in spaces between the first sub-pads SCPD1, and the first sub-pads SCPD1 may be positioned between the second sub-pads SCPD2. In other words, the first sub-pads SCPD1 and the second sub-pads SCPD2 may be arranged in a zigzag pattern with respect to the first direction DR1. However, the inventive concept is not limited thereto, and the first sub-pads SCPD1 and the second sub-pads SCPD2 may be disposed in a row in the first direction DR1, or the pad portion PDP may further include third sub-pads so that the first to third sub-pads may be disposed in three or more rows.

A width w1 of each of the first sub-pads SCPD1 and a width w2 of each of the second sub-pads SCPD2 may be the same. The width w1 of each of the first sub-pads SCPD1 and the width w2 of each of the second sub-pads SCPD2 may be each about 0.25 mm to about 0.35 mm. However, an embodiment of the inventive concept is not limited thereto, and the width w1 of each of the first sub-pads SCPD1 and the width w2 of each of the second sub-pads SCPD2 may be different from each other.

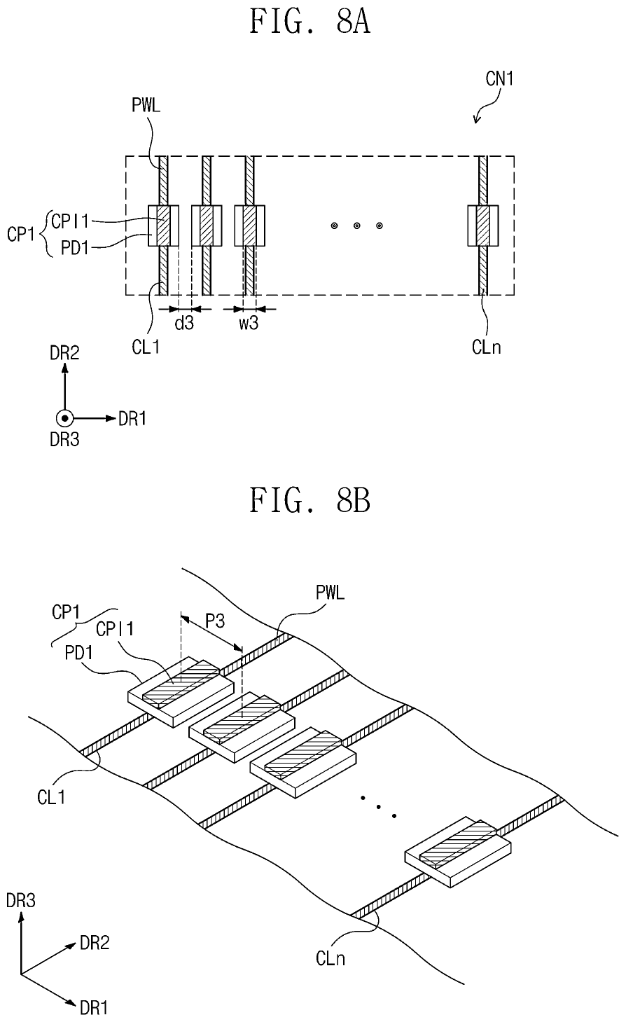

Connection wires CL1 to CLn may be respectively connected to the first sub-pads SCPD1 and the second sub-pads SCPD2. The first sub-pads SCPD1 and the second sub-pads SCPD2 may respectively transmit a power signal to a first connector CN1 (see FIG. 8A) through the connection wires CL1 to CLn. The connection wires CL1 to CLn may be respectively connected to first connection portions CP1 (see FIG. 8A) of the first connector CN1. The number of the connection wires CL1 to CLn may be the same as the number of the first sub-pads SCPD1 and the second sub-pads SCPD2. In other words, the number of the first sub-pads SCPD1 and the second sub-pads SCPD2 may be n, which is the number of the connection wires CL1 to CLn.

Referring to FIGS. 7A and 7B, the connection pads CPD and a power connector CN-P may be in contact with each other. Before the connection pads CPD and the power connector CN-P are in contact with each other, the power connector CN-P may be disposed on the connection pads CPD.

The power connector CN-P may include a first jig plate JPL1 and a plurality of first jig pins JPI1. The first jig plate JPL1 may include an upper surface and a lower surface extending in the first direction DR1 and the second direction DR2. The first jig pins JPI1 may be made of metal for electrical conduction. The first jig pins JPI1 may be attached to the first jig plate JPL1. For example, the first jig pins JPI1 may be attached to the lower surface of the first jig plate JPL1.

The first jig pins JPI1 may include a plurality of first sub-jig pins SJPI1 and a plurality of second sub-jig pins SJPI2. The first sub-jig pins SJPI1 and the second sub-jig pins SJPI2 may each be arranged in the first direction DR1. The first sub-jig pins SJPI1 and the second sub-jig pins SJPI2 may be spaced apart from each other in the second direction DR2.

Referring to FIG. 7A, before moving to the connection pads CPD, the first jig plate JPL1 and the first jig pins JPI1 may be aligned in the first direction DR1. In other words, the first sub-jig pins SJPI1 and the second sub-jig pins SJPI2 may be disposed corresponding to the first sub-pads SCPD1 and the second sub-pads SCPD2, respectively. For example, the first sub-jig pins SJPI1 may overlap the first sub-pads SCPD1, and the second sub-jig pins SJPI2 may overlap the second sub-pads SCPD2. The first sub-jig pins SJPI1 and the second sub-jig pins SJPI2 may be arranged in a zigzag pattern in the first direction DR1.

The first sub-pads SCPD1 arranged in the first direction DR1 may have a first interval P1. The first sub-jig pins SJPI1 arranged in the first direction DR1 may have a second interval P2. The first interval P1 may be a distance between the centers of two adjacent first sub-pads SCPD1 among the first sub-pads SCPD1, and the second interval P2 may be a distance between the centers of two adjacent first sub-jig pins SJPI1 among the first sub-jig pins SJPI1.

According to an embodiment of the inventive concept, the first interval P1 of the first sub-pads SCPD1 along the first direction DR1 and the second interval P2 of the first sub-jig pins SJPI1 may be the same as each other. The first sub-pads SCPD1 may be spaced apart from each other at the first interval P1 in the first direction DR1, and the first sub-jig pins SJPI1 may be spaced apart from each other at the second interval P2 in the first direction DR1. When the first interval P1 and the second interval P2 are the same, the first sub-jig pins SJPI1 may be precisely aligned with and in contact with the first sub-pads SCPD1. In addition, the second sub-pads SCPD2 may be spaced apart from each other at the first interval P1 in the first direction DR1, and the second sub-jig pins SJPI2 may be spaced apart from each other at the second interval P2 in the first direction DR1. Accordingly, when the first interval P1 and the second interval P2 are the same, the second sub-jig pins SJPI2 may be precisely aligned with and in contact with the second sub-pads SCPD2. For example, the first interval P1 and the second interval P2 may be each about 0.8 mm to about 1.0 mm. However, the first interval P1 and the second interval P2 are not limited to these values, and may be adjusted according to the position of the pad portion PDP (see FIG. 4A).

FIGS. 7A and 7B illustrate that the first sub-jig pins SJPI1 and the second sub-jig pins SJPI2 are disposed at constant intervals. However, the respective disposition intervals of the first sub-jig pins SJPI1 and the second sub-jig pins SJPI2 are not limited to these intervals. After the first jig plate JPL1 and the first jig pins JPI1 are aligned with the connection pads CPD, the first jig plate JPL1 and the first jig pins JPI1 may move in the direction opposite to the third direction DR3, that is, toward the connection pads CPD. The first jig plate JPL1 and the first jig pins JPI1 may move in the opposite direction of the third direction DR3 to make contact with the connection pads CPD. The power signal may be transmitted to the connection pads CPD through the first jig pins JPI1. The connection pads CPD may transmit the power signal to the connection wires CL1 to CLn.

FIG. 8A is an enlarged view of a first connector according to an embodiment of the inventive concept illustrated in FIG. 4A. FIG. 8B is a perspective view of the first connector according to an embodiment of the inventive concept.

Referring to FIG. 8A, a first connector CN1 may include a plurality of first connection portions CP1. The first connection portions CP1 may be arranged in the first direction DR1. The first connection portions CP1 may be spaced apart from each other by a third distance d3 in the first direction DR1. According to an embodiment of the inventive concept, the first distance d1 by which the first sub-pads SCPD1 illustrated in FIG. 6 are spaced apart from each other in the first direction DR1 may be different from the third distance d3 by which the first connection portions CP1 are spaced apart from each other in the first direction DR1. The third distance d3 may be smaller than the first distance d1. For example, the third distance d3 may be about 0.15 mm to about 0.25 mm.

Referring to FIGS. 8A and 8B, the first connection portions CP1 may respectively include a plurality of first pads PD1 and a plurality of first connection pins CPI1 disposed on the first pads PD1. The first connection pins CPI1 may be respectively disposed on the centers of the first pads PD1. The first pads PD1 and the first connection pins CPI1 may be electrically connected to each other. The first connection pins CPI1 may include metal for electrical conduction. A width of each of the first pads PD1 may be the same as the width w1 of each of the first sub-pads SCPD1 illustrated in FIG. 6. A width w3 of each of the first connection pins CPI1 may be smaller than the width of each of the first pads PD1. For example, the width w3 of each of the first connection pins CPI1 may be about 0.18 mm to about 0.22 mm.

The first connection portions CP1 arranged in the first direction DR1 may have a third interval P3. The third interval P3 may be a distance between the centers of two adjacent first connection portions CP1 among the first connection portions CP1. Specifically, the third interval P3 may be a distance between the centers of two adjacent first connection pins CPI1 among the first connection pins CPI1.

According to an embodiment of the inventive concept, the first interval P1 of the first sub-pads SCPD1 illustrated in FIG. 7A along the first direction DR1 may be different from the third interval P3 of the first connection portions CP1 along the first direction DR1. The third interval P3 may be smaller than the first interval P1. For example, the third interval P3 may be about 0.4 mm to about 0.6 mm.

The first connection portions CP1 may receive power signals through connection wires CL1 to CLn. The first connection portions CP1 may then transmit the power signals to power wires PWL. The connection wires CL1 to CLn and the power wires PWL may extend in the second direction DR2. The power wires PWL may transmit the power signals to a flexible circuit board FPC (see FIG. 4A). The power signals correspond to the voltages used to drive the display module DM illustrated in FIG. 4A. That is, the power signals, which are DC voltages, are used to drive the display module DM and are distinct from the data voltages used to display images on the display module DM. Therefore, even if noise is generated by the first connection portions CP1 during the process of transmitting the power signals from a main circuit board MCB via the first connection portions CP1 to the power wires PWL, it does not effect on the images displayed by the display module DM.

The number of the first connection portions CP1 may be the same as the number of the connection wires CL1 to CLn. That is, the number of the first connection portions CP1 may be n, which is the number of the connection wires CL1 to CLn. In addition, the number of the first connection portions CP1 may be the same as the number of the first sub-pads SCPD1 and the second sub-pads SCPD2 illustrated in FIG. 6.

Referring to FIGS. 6 to 8B, when the first connector CN1 and a separate power connector are connected, the power connector may be imprecisely aligned on the first connector CN1 due to process errors caused by the narrow interval between the first connection portions CP1 included in the first connector CN1 and the small widths of the first connection pins CPI1. This can result in contact failure between the first connection pins CPI1 and the first jig pins JPI1.

The circuit board PCB (see FIG. 4A) according to an embodiment of the inventive concept may be spaced apart from the first connector CN1 and include connection pads CPD in direct contact with the power connector CN-P. Since the connection pads CPD are arranged at the third interval P3, the first jig pins JPI1 can be more freely arranged to correspond to the connection pads CPD. As a result, the connection pads CPD and the first connection pins CPI1 can be easily aligned and coupled. In addition, a separate bridge substrate for increasing the degree of contact between the circuit board PCB (see FIG. 4A) and the main circuit board MCB (see FIG. 4A) is not required, thereby simplifying the manufacturing process of the display module DM (see FIG. 4A).

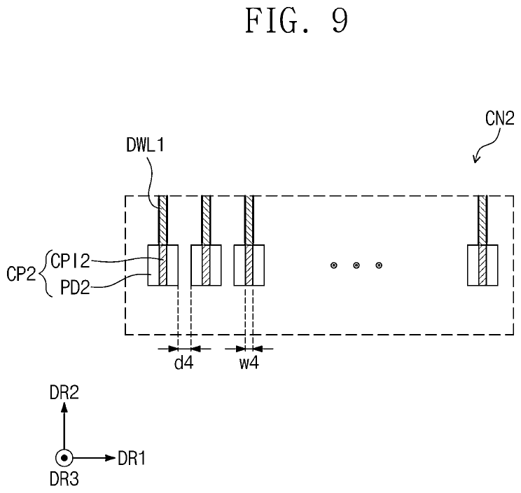

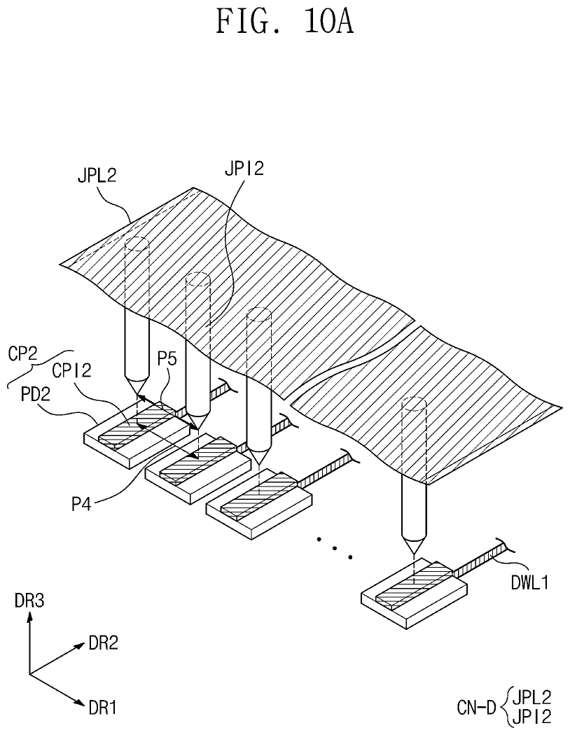

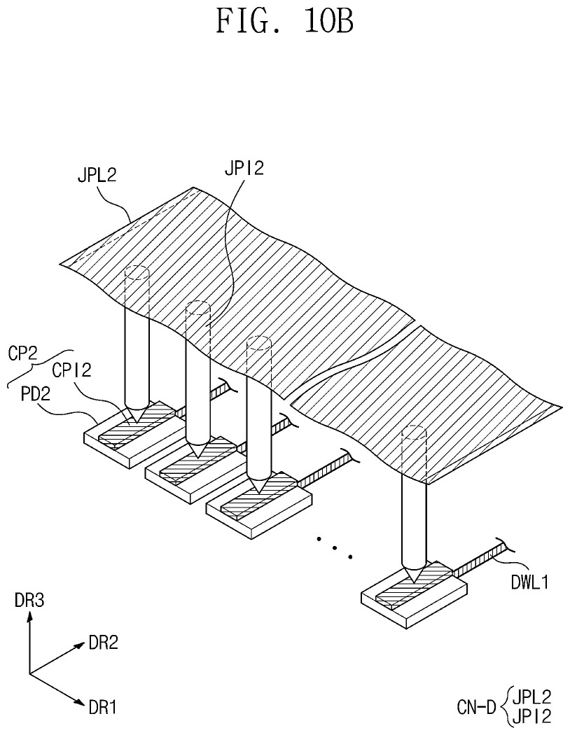

FIG. 9 is an enlarged view of a second connector according to the embodiment of the inventive concept illustrated in FIG. 4A. FIGS. 10A and 10B are diagrams illustrating the coupling of the second connector and a signal connector according to an embodiment of the inventive concept.

Referring to FIG. 9, a second connector CN2 may include a plurality of second connection portions CP2. The second connection portions CP2 may be arranged in the first direction DR1. The number of the second connection portions CP2 may be smaller than the number of the first connection portions CP1 (see FIG. 8A). For example, the number of the first connection portions CP1 may be about 60, and the number of the second connection portions CP2 may be about 40. The second connection portions CP2 may be spaced apart from each other by a fourth distance d4 in the first direction DR1. According to an embodiment of the inventive concept, the third distance d3 by which the first connection portions CP1 illustrated in FIG. 8A are spaced apart from each other in the first direction DR1 may be the same as the fourth distance d4 by which the second connection portions CP2 are spaced apart from each other in the first direction DR1. For example, the fourth distance d4 may be about 0.15 mm to about 0.25 mm.

Referring to FIGS. 9 and 10B, the second connection portions CP2 may respectively include a plurality of second pads PD2 and a plurality of second connection pins CPI2 disposed on the second pads PD2. The second connection pins CPI2 may positioned at the centers of the second pads PD2. The second pads PD2 and the second connection pins CPI2 may be electrically connected to each other. The second connection pins CPI2 may include metal for electrical conduction. A width of each of the second pads PD2 may be the same as a width of each of the first pads PD1 illustrated in FIG. 8A. A width w4 of each of the second connection pins CPI2 may be smaller than the width w3 of each of the first connection pins CPI1 illustrated in FIG. 8A. For example, the width w4 of each of the second connection pins CPI2 may be about 0.1 mm to about 0.14 mm.

The second connector CN2 and a signal connector CN-D may be in contact with each other. Before the second connection portions CP2 and the signal connector CN-D are in contact with each other, the signal connector CN-D may be disposed on the second connection portions CP2. The signal connector CN-D may include a second jig plate JPL2 and a plurality of second jig pins JPI2. The second jig plate JPL2 may include an upper surface and a lower surface extending in the first direction DR1 and the second direction DR2. The second jig pins JPI2 may include metal for electrical conduction. The second jig pins JPI2 may be attached to the second jig plate JPL2. For example, the second jig pins JPI2 may be attached to the lower surface of the second jig plate JPL2.

Referring to FIG. 10A, a process of aligning the second jig plate JPL2 and the second jig pins JPI2 in the first direction DR1 may be performed before moving the second jig plate JPL2 and the second jig pins JPI2 to the second connector CN2 (see FIG. 9). That is, the second jig pins JPI2 may be positioned to correspond to the second connection portions CP2. Specifically, the second jig pins JPI2 may be positioned to correspond with the second connection pins CPI2.

The second connection portions CP2 arranged in the first direction DR1 may have a fourth interval P4, and the second jig pins JPI2 arranged in the first direction DR1 may have a fifth interval P5. The fourth interval P4 may be the distance between the centers of two adjacent second connection portions CP2 among the second connection portions CP2, and the fifth interval P5 may be the distance between the centers of two adjacent second jig pins JPI2 among the second jig pins JPI2. The fourth interval P4 may also be the same as the distance between the centers of two adjacent second connection pins CPI2 among the second connection pins CPI2.

The fourth interval P4 of the second connection portions CP2 along the first direction DR1 may be the same as the fifth interval P5 of the second jig pins JPI2. When the fourth interval P4 and the fifth interval P5 are the same, the second jig pins JPI2 may be precisely aligned and in contact with the second connection portions CP2. Specifically, the second jig pins JPI2 may contact the centers of the second connection pins CPI2. For example, the fourth interval P4 and the fifth interval P5 may each be about 0.4 mm to about 0.6 mm. FIGS. 10A and 10B illustrate the second jig pins JPI2 disposed at equal intervals, but the disposition interval of the second jig pins JPI2 is not limited thereto.

After the second jig plate JPL2 and the second jig pins JPI2 are aligned with the second connection portions CP2, the second jig plate JPL2 and the second jig pins JPI2 may move in the direction opposite to the third direction DR3, that is, toward the second connection portions CP2. The second jig plate JPL2 and the second jig pins JPI2 may move in the opposite direction of the third direction DR3 to make contact with the second connection portions CP2.

An image signal may be transmitted to the second connection pins CPI2 through the second jig pins JPI2. The second pads PD2 electrically connected to the second connection pins CPI2 may transmit the image signal to first signal wires DWL1. The first signal wires DWL1 extending in the second direction DR2 may transmit the image signal to the timing controller T-CON (see FIG. 4A).

A circuit board according to an embodiment of the inventive concept may be spaced apart from a first connector and include connection pads that are in direct contact with a power connector. Since the connection pads are arranged at a greater interval than the interval at which connection portions of the first connector are arranged, jig pins of the power connector can be freely arranged to correspond to the connection pads. As a result, the connection pads and the jig pins can be easily aligned and coupled.

In addition, a separate bridge substrate for increasing the degree of contact between a printed circuit board and a main circuit board is not required, thereby simplifying the manufacturing process for a display module.

The description above has referenced embodiments of the inventive concept. However, those skilled in the art or with ordinary skill in the relevant technical field will understand that various modifications and changes may be made to the inventive concept without departing from the spirit and scope of the inventive concept described in the claims below.

Therefore, the technical scope of the inventive concept is not limited to the contents described in the detailed description of the specification.

What is claimed is:

1. A display device comprising:
a display panel configured to display an image; and
a circuit board electrically connected to the display panel,
wherein the circuit board includes
a plurality of power wires,
a plurality of signal wires,
a first connector including a plurality of first connection portions, each electrically connected to one of the power wires,
a plurality of connection pads, each electrically connected to one of the first connection portions, and
a second connector including a plurality of second connection portions, each electrically connected to one of the plurality of signal wires, and
a first interval between the first connection portions along a first direction is different from a second interval between the connection pads along the first direction.

2. The display device of claim 1, wherein the connection pads comprise: a plurality of first sub-pads arranged in the first direction; and
a plurality of second sub-pads spaced apart from the plurality of first sub-pads in a second direction that intersects the first direction, and arranged along the first direction.

3. The display device of claim 2, wherein the first sub-pads and the second sub-pads are arranged in a zigzag pattern along the first direction.

4. The display device of claim 2, wherein an interval of the first sub-pads and an interval of the second sub-pads are same as each other.

5. The display device of claim 1, wherein the second interval is greater than the first interval.

6. The display device of claim 1, wherein each of the first connection portions comprises a plurality of first pads, and a plurality of first connection pins electrically connected to the first pads, and
each of the second connection portions comprises a plurality of second pads, and a plurality of second connection pins electrically connected to the second pads.

7. The display device of claim 6, wherein the first pads and the second pads are each arranged along the first direction, wherein the first pads are separated from each other by a first distance, and the second pads are separated from each other by the first distance.

8. The display device of claim 6, wherein the first pads and the second pads are each arranged along the first direction, wherein the first pads are separated from each other by a first distance and the second pads are separated from each other by a second distance different from the first distance.

9. The display device of claim 7, wherein a first width of each of the first connection pins along the first direction and a second width of each of the second connection pins along the first direction are different.

10. The display device of claim 1, wherein the first connector and the connection pads are spaced apart from each other on a plane.

11. The display device of claim 10, wherein the circuit board further comprises connection wires for electrically connecting the first connector and the connection pads.

12. The display device of claim 1, wherein a number of the first connection portions is greater than a number of the second connection portions.

13. An electronic device comprising:
a display panel configured to display an image;
a circuit board electrically connected to the display panel; and
a main circuit board including a power connector for supplying a power signal to the circuit board, and a signal connector for supplying an image signal,
wherein the circuit board includes
a plurality of power wires,
a plurality of signal wires,
a first connector including a plurality of first connection portions, each electrically connected to one of the power wires,
a plurality of connection pads connected to the power connector, each electrically connected to one of the first connection portions, and
a second connector connected to the signal connector, and including a plurality of second connection portions each electrically connected to one of the plurality of signal wires, and
a first interval of the first connection portions along a first direction and a second interval of the connection pads along the first direction are different.

14. The electronic device of claim 13, wherein the first connector and the connection pads are spaced apart from each other on a plane, and
the circuit board further comprises connection wires electrically connecting the first connector and the connection pads.

15. The electronic device of claim 13, wherein the power connector comprises:
a first jig plate; and
a plurality of first jig pins disposed on the first jig plate, and in contact with the connection pads.

16. The electronic device of claim 15, wherein an interval of the first jig pins along the first direction is the same as the second interval.

17. The electronic device of claim 14, wherein the signal connector comprises:
a second jig plate; and
a plurality of second jig pins disposed on the second jig plate, and in contact with the second connection portions.

18. The electronic device of claim 17, wherein an interval of the second jig pins along the first direction is the same as a third interval of the second connection portions along the first direction.

19. The electronic device of claim 13, wherein a number of the first connection portions is greater than a number of the second connection portions.

20. The electronic device of claim 13, wherein a first width of each of the first connection portions along the first direction is different from a second width of each of the second connection portions along the first direction.
